(19) United States
(12) Patent Application Publication
(10) Pub. No.: US 2002/0141348 A1
(43) Pub. Date: Oct. 3, 2002

(54) Remote diagnostic tool for a media delivery network

(76) Inventors: Scott Swix, Duluth, GA (US); P. Thomas Watson, Alpharetta, GA (US); Randy S. Zimler, Gainesville, GA (US); James Gray, Atlanta, GA (US); Timothy H. Weaver, Alpharetta, GA (US)

Correspondence Address: MERCHANT & GOULD PC, P.O. BOX 2903, MINNEAPOLIS, MN, 55402-0903, US

(21) Appl. No.: 09/892,727

(22) Filed: Jun. 27, 2001

Related U.S. Application Data
(60) Provisional application No. 60/281,206, filed on Apr. 2, 2001.

(51) Int. Cl. G01R 31/08; G06F 11/00; G08C 15/00; H04J 1/16; H04J 3/14

(52) U.S. Cl. 370/252; 370/250; 375/222

(57) ABSTRACT

A Media Delivery Diagnostic System can be deployed in response to a customer complaint or in an autonomous fashion. When a customer complains to a Media Delivery Service Provider, the complaint can be passed to a diagnostic service center. The diagnostic service center can initiate a query or command and transmit the query or command to a Media Distribution Device (MDD). The query or command can be processed by an intelligent diagnostic agent residing in the MDD. When the intelligent diagnostic agent receives the query or command, it can perform a diagnostic evaluation of the MDD and any other devices connected to the MDD. The intelligent diagnostic agent can transmit diagnostic data back to the diagnostic service center. The diagnostic data may be operational data and/or operational parameters related to the MDD, the identification of a problem with the MDD, or an indication that the intelligent diagnostic agent failed to identify a problem in be MDD. In response to the receipt of diagnostic data from the MDD, the diagnostic service center can send a supplemental query or command to instruct the intelligent diagnostic agent to perform a remedial action.

### FIELD OF THE INVENTION

The present invention generally relates to a media delivery service system. More particularly, the present invention relates to enabling the remote diagnosis of components within a media delivery service system.

### BACKGROUND OF INVENTION

More than ever before, residential consumers are being provided with a wealth of media resources. While cable television, the Internet, and on-demand media have been available for years, recently developed high-speed broadband technologies are enhancing the delivery of these media services. These technologies have made it possible to increase the variety of available media services and to enhance the ability of the user to interact with the media delivery system to tailor media delivery to the user's preferences. Satellite communications, asymmetric digital subscriber lines (ADSL), and broadband cable are providing new high-throughput connections to media delivery services. Media services consumers are commonly establishing wireless connections to satellites, telephony-based connections to ADSL, and broadband cable connections to the media service providers. Typically, these connections are processed by a Media Distribution Device that processes media content and data and routes the media and/or data to media presentation devices, such as a television or personal computer. A conventional Set-top Box is an example of a Media Distribution Device.

Unfortunately, because these high-speed media delivery technologies are so new, customers often have trouble establishing and maintaining a properly functioning media delivery system. Typical problems include low signal strengths, bit error rates, problems with physical connections between devices in the media delivery system, and compatibility problems. Often, the Media Distribution Device will be connected to other devices such as a hub, a personal computer, a television, or another Media Distribution Device. When capability issues arise between these devices, the performance of the entire media delivery system can be adversely affected. Compatibility problems can be caused by hardware, software, or other means. Moreover, most customers are not technically savvy enough to troubleshoot the problems on their own.

Traditionally, customer problems are addressed by providing a telephone-based technical support line or by providing an onsite technician service call. The typical technical support call involves having the customer describe the system configuration. For example, in the case of an ADSL Internet customer, the technical support technician may ask the customer to verify that the customer's personal computer has the requisite hardware and software configuration to communicate with an ADSL modem. The technical support technician will often ask the customer to execute various diagnostic procedures. If the technical support diagnosis fails, an onsite technician service call will normally be provided. The on-site technician will troubleshoot the system and attempt to place the media delivery system in an operational condition.

Both technical support line technicians and on-site technicians are very expensive resources. For example, technical support cost studies indicate that it costs about as much to send a technician to perform an on-site service call as a customer pays for one or two month's worth of services. Accordingly, technical support service calls negatively affect the profitability of a media distribution service provider and are to be avoided.

Another problem with on-site technical service calls relates to the behavior of the service call technicians. Often, service call technicians are over-booked and are pressured to complete a service call in a very limited amount of time. Consequently, service technicians are prone to replace a Media Distribution Device, rather than to troubleshoot and/or repair an existing Media Distribution Device. Studies indicate that only about 5% of Media Distribution Devices that are returned by service call technicians are actually defective. Usually, returned Media Distribution Devices are simply improperly configured. Returning Media Distribution Devices to a manufacturer, especially when the Media Distribution Device is not actually defective, is extremely expensive. Therefore, there is a need to minimize service calls and all other interaction between customers and service personnel, because such interaction is expensive. In addition, there is a need to troubleshoot and repair Media Distribution Devices in the field, rather than swapping them with new Media Distribution Devices.

One approach to solving this problem has been to install self-diagnostic tools on the Media Distribution Device. Unfortunately, there are several shortcomings to this approach. Conventional Media Distribution Devices have been equipped with a slow (low bandwidth) trouble-shooting connection, such as a 2400-baud modem. This connection allows a technician to upload data from the Media Distribution Device to a service center for troubleshooting. Unfortunately, the connection is slow and, therefore, service technicians are prone to avoid using the connection. In addition, the slow connection cannot provide real-time diagnostic functionality, but can only provide historical performance data, which is less valuable for trouble-shooting. Moreover, many customers disconnect the modem connection from their telephone lines, thereby requiring an on-site technician service call to connect the modem for uploading data.

Another problem with the installation of self-diagnostic tools is that memory is one of the most expensive parts of a conventional Media Distribution Device. Consequently, any self-diagnostic application that is installed in the memory of the Media Distribution Device must be small, so as to minimize the use of the memory resources. Because the conventional self-diagnostic application is small, it cannot be very sophisticated. Typically, such self-diagnostic applications have not been comprehensive diagnostic tools and aren't sophisticated enough to direct a customer through a comprehensive troubleshooting procedure. Similarly, in the satellite distribution context, transponder space is very valuable. Using transponder resources for self-diagnostic applications is, therefore, expensive and heretofore cost prohibitive.

Therefore, there is a need in the art for a media delivery system diagnostic tool that provides for remote, high-speed, realtime system diagnosis. The tool should provide for system diagnosis to be performed by a central service center in communication with a local intelligent diagnostic agent. The tool should be readily accessible during off-peak times for automated diagnostics and Media Distribution Device system software updating. The tool also should permit the temporary installation of diagnostic software for troubleshooting and the subsequent removal of that software to conserve valuable memory resources.

### SUMMARY OF THE INVENTION

A media delivery diagnostic system can be deployed in response to a customer complaint or in an autonomous fashion. When a customer complains to a media delivery service provider, the complaint can be passed to a diagnostic service center. The diagnostic service center can initiate a query or command and transmit the query or command to a Media Distribution Device (MDD). The query or command can be processed by an intelligent diagnostic agent residing in the MDD. When the intelligent diagnostic agent receives the query or command, it can perform a diagnostic evaluation of the MDD and any other devices connected to the MDD. The intelligent diagnostic agent can transmit diagnostic data back to the diagnostic service center. The diagnostic data may be operational data and/or operational parameters related to the MDD, the identification of a problem with the MDD, or an indication that the intelligent diagnostic agent failed to identify a problem in the MDD. In response to the receipt of diagnostic data from the MDD, the diagnostic service center can send a supplemental query or command to instruct the intelligent diagnostic agent to perform a remedial action.

Remedial actions may include the replacement of the intelligent diagnostic agent or the replacement of another program module stored in the system memory of the MDD. Alternatively, the remedial action may require a service call to the physical location of the media distribution device. Thus, the media delivery system can be self-diagnosing, in that a performance problem can be automatically identified and remedied in a media distribution device. Advantageously, the use of a broadband communication link between the media distribution service provider and the media delivery device enables such self-diagnosis to be performed in real-time, during off-peak use hours, and with little adverse impact on overall system performance.

The various aspects of the present invention may be more clearly understood and appreciated from a review of the following detailed description of the disclosed embodiments and by reference to the drawings and claims.

### BRIEF DESCRIPTION OF THE DRAWINGS

FIG. 1 is a block diagram of an exemplary operating environment in which embodiments of the present invention may be implemented.

FIG. 2 is a block diagram depicting some of the primary components of an exemplary Media Distribution Device.

FIG. 3 is a block diagram depicting a media delivery diagnostic system that is an exemplary embodiment of the present invention.

FIG. 4 is a flow chart depicting an exemplary method for providing remote media delivery system diagnosis.

### DETAILED DESCRIPTION

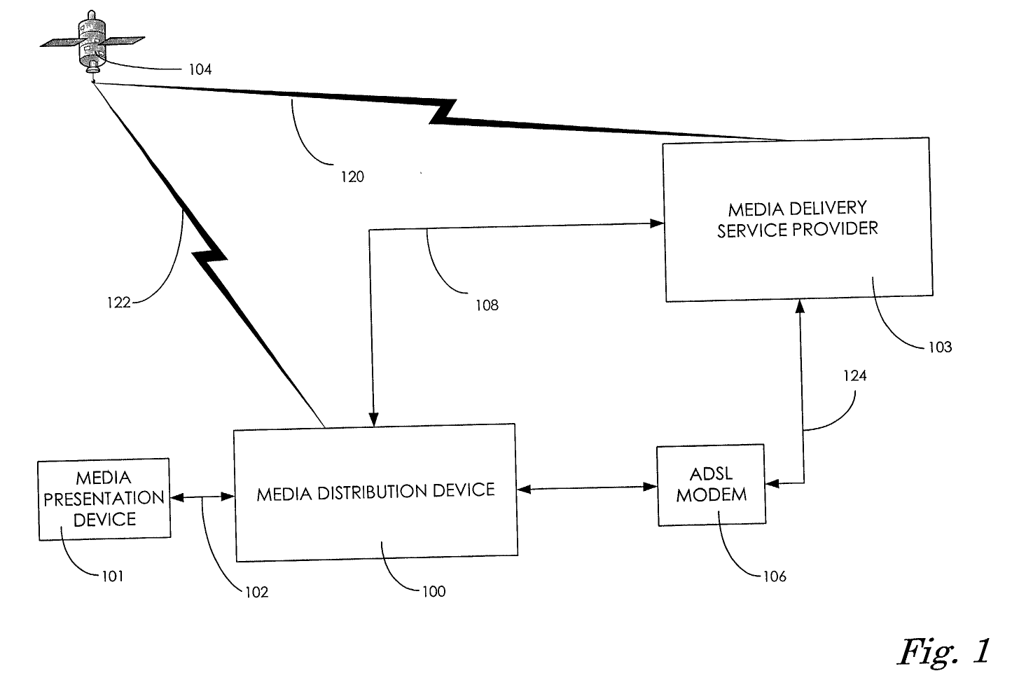

FIG. 1 is a block diagram of an exemplary operating environment in which embodiments of the present invention may be implemented. Media content is typically delivered to a customer by means of a Media Distribution Device 100. The most common Media Distribution Devices are conventional Set-Top Boxes (STBs). The Media Distribution Device (MDD) 100 can provide media content and/or data to a media presentation device 101 over a communication link 102. The most common example of a media presentation device 101 is a conventional television. Typically, the MDD 100 will deliver media content only to media presentation device 101. However, newer-generation media presentation devices 101 have the ability to process data received from the Media Distribution Device 100. Such data may include information pertaining to the presentation of the media content on the media presentation device 101.

Another example of a media presentation device 101 is a conventional personal computer. The personal computer can receive media content, such as Internet content from the Media Distribution Device 100 and present it to a customer/user. As is well known, a personal computer can also process data received from the Media Distribution Device 100 to format the presentation of the delivered media content.

The MDD 100 can receive media content and data from one or more sources. In the example of FIG. 1, the MDD 100 is depicted receiving media and data from a Media Delivery Service Provider 103. An example of a Media Delivery Service Provider is a cable T.V. provider, a satellite T.V. provider, an Internet service provider, and a telephone service provider. Notably, the media content and data may be delivered over a single communication link or may be delivered over separate communication links.

In the example of FIG. 1, the Media Delivery Service Provider 103 can provide media content and data to the MDD 100 via an Asymmetric Digital Subscriber Line (ADSL) modem 106. The Media Delivery Service Provider 103 may also provide media content and data to the MDD 100 via a satellite 104. The satellite can deliver media content and data directly to the MDD 100 over a communications link 122. Such a direct link usually involves the use of a small satellite dish in conjunction with the MDD 100. The satellite 104 can also deliver the media content and data to the Media Delivery Service Provider 103 via another communication link 120. This media content and data may be rerouted to the MDD 100 from the Media Delivery Service Provider 103 over a separate communication link.

The MDD 100 may also have a direct communication link 108 with the Media Delivery Service Provider 103. Such a link might be a conventional 2400-baud modem connection to the Media Delivery Service Provider 103. This communication link 108 may also be a direct hardwire connection or a network connection, such as an Ethernet connection.

In any event, the MDD 100 receives media content and data from a Media Delivery Service Provider 103 and delivers the media content and/or data to the media presentation device 101 for presentation to the customer. Typically, the MDD 100 can communicate in two-directions over the communication links 108 and 124. That is, the MDD 100 can respond to queries and/or commands received from the Media Delivery Service Provider 103 and return data and/or messages, in response to the receipt of a query or command. The Simple Network Management Protocol (SNMP) is a standard that has been developed to standardize such two-way communication between the MDD 100 and the Media Delivery Service Provider 103. Typically, an SNMP agent will be installed in the MDD 100 and will coordinate all SNMP communications between the MDD 100 and the Media Delivery Service Provider 103. Notably, such two-way communications are not currently available over communications link 122 with the satellite 104.

When a customer associated with the media presentation device 101 experiences a problem, the customer will typically contact a technical support unit associated with the Media Delivery Service Provider 103. An exemplary embodiment of the present invention permits that remote diagnosis of the MDD 100 and/or the media presentation device 101 by the Media Delivery Service Provider 103. The Media Delivery Service Provider 103 may also initiate a diagnosis automatically (i.e., without customer initiation). The Media Delivery Service Provider 103 may also use an exemplary embodiment of the present invention to upload software, media content, and/or data to the Media Distribution Device 100 or the media presentation device 101. This upload can be automatic or in response to a customer request.

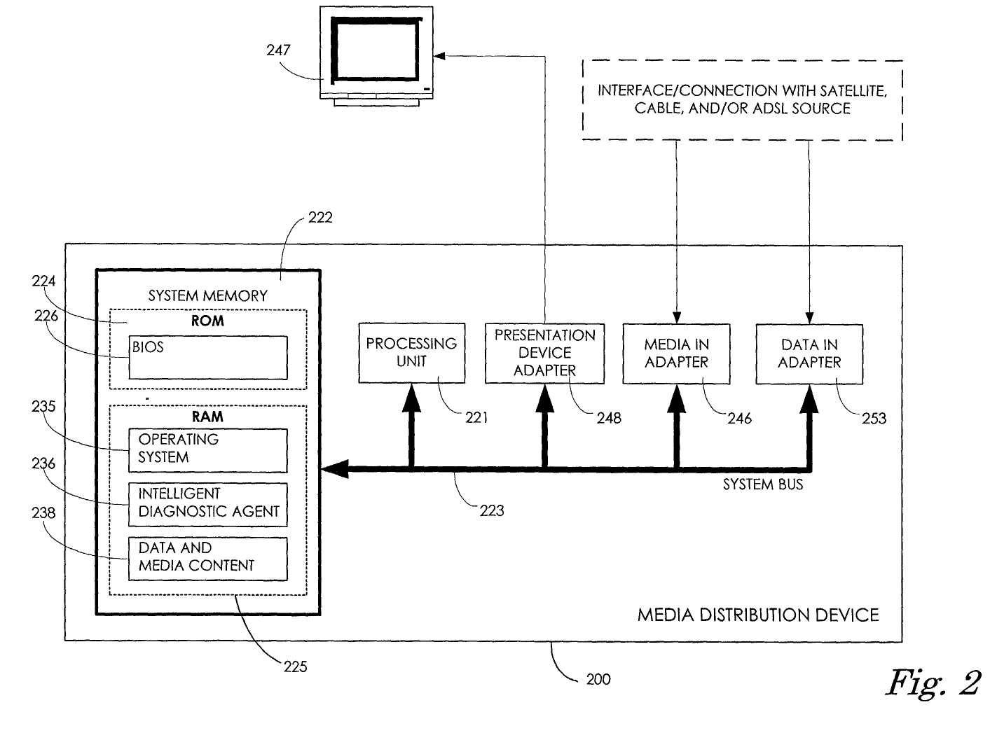

FIG. 2 is a block diagram depicting some of the primary components of an exemplary Media Distribution Device. The conventional Media Distribution Device 200 includes a processing unit 221, a system memory 222, and a system bus 223 that couples the system memory to the processing unit. The system memory 222 includes read-only memory (ROM) 224 and random access memory (RAM) 225. A basic input/output system 226 (BIOS) contains rudimentary code to execute basic functions, such as system start-up. The BIOS 226 is stored in the ROM 224. Various program modules may be stored in the RAM 225. Such program modules might include an operating system 235, and intelligent diagnostic agent 236 (such as an SNMP agent), and data and media content 238.

Although not depicted in FIG. 2, the MDD 200 could also include a hard drive or other non-volatile memory for long-term storage of program modules such as the operating system 235, the intelligent diagnostic agent 236, and the data and media content 238. The hard drive may be connected to the MDD 200 via a hard drive interface. Similarly, other peripheral devices could be connected to the MDD with other interfaces not depicted in FIG. 2. Moreover, the MDD could also be equipped with an input device, such as keyboard and/or mouse.

The MDD 200 can also include a video adapter 248 or other adapter for delivery of media content and/or data to a media presentation device 247. The MDD 200 also includes a Media In Adapter 246 and a Data In Adapter 253. These adapters permit connection of the MDD 200 to a communication link for one-way and/or two-way communication with a Media Delivery Service Provider. The Media In Adapter 246 and the Data In Adapter 253 may incorporate a modem and/or other communication device.

The MDD 200 receives media content and data and makes the media content and data available to other internal components by way of the system bus 223. The processing unit 221 can route the media content and/or data in accordance with the instructions of the operating system 235 and/or other applications executed in the RAM 225. In addition, the processing unit 221 may store the media content and data in the RAM 225 for subsequent use. The processing unit 221 may also direct the media content and/or data to the media presentation device 247 via the presentation device adapter 248.

The intelligent diagnostic agent 236 may be executed by the processing unit 221 in response to a command received from the Media Delivery Service Provider or any other source. The command may be formatted in accordance with the SNMP protocol. Once the intelligent diagnostic agent 236 has been executed, the agent may perform various system diagnoses to evaluate the performance of the MDD 200. The intelligent diagnostic agent 236 may then return diagnostic data to the Media Delivery Service Provider identifying the problem or indicating a failure to identify the problem. The Media Delivery Service Provider may return a query for more information or a command to perform a remedial function, such as downloading a software update from the Media Delivery Service Provider or changing one or more operation parameters of the MDD 200. Notably, the intelligent diagnostic agent 236 also can be used to perform diagnostic functions on the media presentation device 247 or any other device attached to the MDD 200. Such a diagnosis may require the Media Delivery Service Provider to query the intelligent diagnostic agent 236 for an identification of the devices connected to the MDD 200.

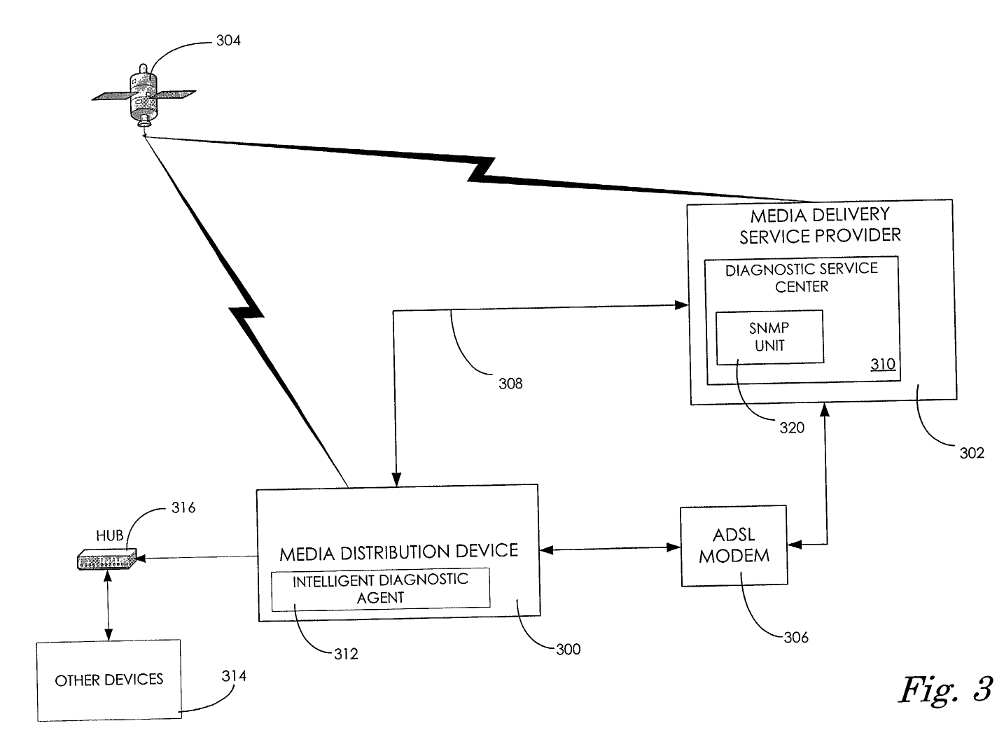

FIG. 3 is a block diagram depicting a Media Delivery Diagnostic System that is an exemplary embodiment of the present invention. In this exemplary operating environment, the MDD 300 is connected to a hub 316, which permits the connection of one or more other devices 314. As described above in connection with FIG. 2, the MDD 300 has a resident intelligent diagnostic agent 312.

The Media Delivery Service Provider 302 has a diagnostic service center 310 associated with it. The diagnostic service center 310 is operative to communicate with the MDD 300 via the satellite 304, a direct link 308, and/or a DSL modem 306. A broadband connection between the Media Delivery Service Provider 302 and the MDD 300 is preferable, because it permits the diagnostic service center 310 to troubleshoot the MDD 300 in real-time and can support an “always-on” connection. Thus, the diagnostic service center can query for and obtain diagnostic information related to the MDD 300 and then send remedial action commands to the intelligent diagnostic agent 312 to remedy the problem within a very short time frame. Low-bandwidth connections, such as the conventional 2400-baud connection 308, require the diagnostic service center 310 to obtain diagnostic data that is historical rather than current (i.e., not realtime) and to diagnose the MDD 300 based on historical data, rather than current data. Because a broadband connection can maintain an always-on status, the diagnostic service center can autonomously query the MDD 300 during off-peak hours of operation, thereby reducing the impact on system resources.

Although the broadband connection depicted in FIG. 3 is supported by means of an ADSL modem 306, virtually any broadband technology can be used to implement an exemplary embodiment of the present invention. For example, a conventional broadband cable-T.V. connection between the Media Delivery Service Provider 302 and the MDD 300 can be used. Unfortunately, current broadband cable-T.V. protocols are not as secure as an ADSL broadband communication link. Broadband cable-T.V. signals can be intercepted and deciphered, while the communication link between the ADSL modem 306 and the Media Delivery Service Provider 302 can be implemented as a Private Virtual Network that is not shared by other users. Thus, an ADSL broadband connection between the MDD 300 and the Media Delivery Service Provider 302 is preferred to other available broadband connections.

The Media Delivery Diagnostic System depicted in FIG. 3 can be implemented in response to a customer complaint or in an autonomous fashion. When a customer complains to the Media Delivery Service Provider 302, the complaint can be passed to the diagnostic service center 310. The diagnostic service center 310 can initiate a query or command and transmit the query or command to the MDD 300. The query or command may be first processed by an SNMP unit 320 in the diagnostic service center 310 so that the query or command can be packaged for processing by an intelligent diagnostic agent 312 residing in the MDD 300. When the intelligent diagnostic agent 312 receives the query or command, it can perform a diagnostic evaluation of the MDD 300, the hub 316, and any other devices 314 connected to the MDD. Notably, the ADSL modem 306 may be an integrated component of the MDD 300. In this case, the intelligent diagnostic agent 312 also could diagnose any problems with the ADSL modem 306.

The intelligent diagnostic agent 312 can transmit diagnostic data back to the diagnostic service center 310. The diagnostic data may simply be operational data and/or operational parametersrelated to the MDD 300, the identification of a problem associated with the MDD 300, or an indication that the intelligent diagnostic agent failed to identify a problem in the MDD 300.

In response to the receipt of diagnostic data from the MDD 300, the diagnostic service center 310 can send a supplemental query or command to instruct the intelligent diagnostic agent 312 to perform a remedial action. For example, the intelligent diagnostic agent may be instructed to download an updated version of an operating system to replace an existing operating system in the MDD 300. If the problem cannot be remedied, the intelligent diagnostic agent 312 may be instructed to enter the identification of the MDD 300 in a service log for a subsequent arrangement for an on-site technical service call.

Those skilled in the art will appreciate that the intelligent diagnostic agent 312 may work completely autonomously or may interact with an on-site customer and/or technician. An interactive diagnostic session may involve presenting a user interface over a media presentation device and receiving input from the customer an/or technician via an input device connected to the presentation device or the MDD 300.

In one embodiment of the present invention, an initial diagnostic step may include a determination of whether the Media Delivery Service Provider 302 is properly communicating with the MDD 300 via the preferred connection. For example, the Media Delivery Service Provider 302 may first check the ADSL modem 306 and/or the ADSL communication link to verify that the Media Delivery Service Provider can properly communicate with the MDD 300. If the connection is operative, the diagnostic session can proceed. If, on the other hand, the connection is not operative, the Media Delivery Service Provider may attempt to remedy the problem through other communication links, such as through the satellite 304. For example, the Media Delivery Service Provider might attempt to update the MDD's 300 operating system and/or ADSL modem driver by sending a command to the intelligent diagnostic agent 312 over a one-way communication link between the MDD and the satellite 304. If such a one-way remedial action fails, the Media Delivery Service Provider may initiate the arrangement of an on-site technician service call.

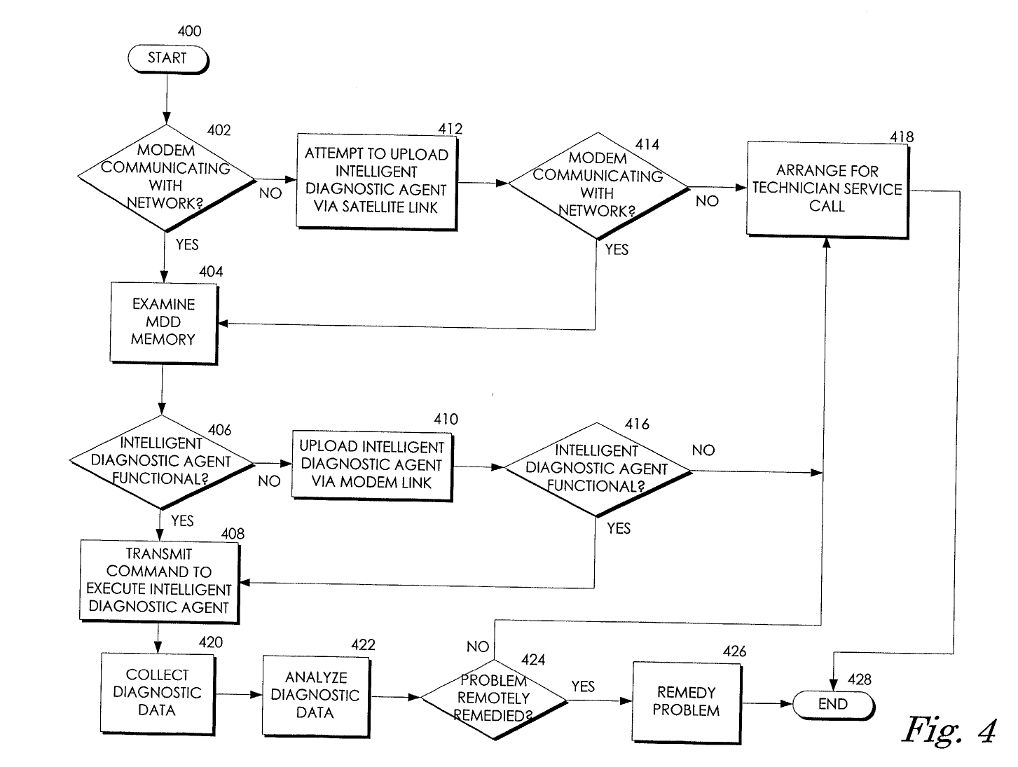

FIG. 4 is a flow chart depicting an exemplary method for providing remote media delivery system diagnostics. It will be appreciated that the method of FIG. 4 is simply one embodiment of the present invention for diagnosing a media delivery service system. Those skilled in the art will appreciate that the method may be used for other communication systems and may be modified to accommodate the various policies of communication system providers. For example, many such communication system service providers would implement various security and/or privacy steps that are not depicted in FIG. 4.

The method of FIG. 4 starts at step 400 and proceeds to decision block 402. At decision block 402, a determination is made as to whether the modem is communicating with the network. In the example of FIG. 3, this step may be performed by the diagnostic service center 310 to determine whether the ADSL modem 306 is properly communicating with the Media Delivery Service Provider 302. If the modem is properly communicating with the network, the method branches to step 404. At step 404, the memory of the MDD is examined. This may be the ROM, the RAM or the non-volatile (e.g., hard drive) memory of the MDD. The method proceeds from step 404 to decision block 406.

At decision block 406, a determination is made as to whether an intelligent diagnostic agent in the MDD memory is functional. If the intelligent diagnostic agent is functional, the method branches to step 408. At step 408, a command is transmitted to the MDD to execute the intelligent diagnostic agent. The method proceeds to step 420. At step 420, diagnostic data related to the MDD is collected. The method then proceeds to step 422 and the diagnostic data is analyzed.

The method proceeds from step 422 to decision block 424. At decision block 424, a determination is made as to whether an identified problem can be remotely remedied. If the problem can be remedied, the method branches from decision block 424 to step 426. At step 426, the problem is remedied. The method then proceeds to step 428 and ends.

Returning now to decision block 424, if a determination is made that the problem cannot be remotely remedied, the method branches to step 418. At step 418, a technician service call is arranged so that the problem can be remedied by an on-site technician. The method proceeds from step 418 to step 428 and ends.

Returning now to decision block 402, if a determination is made that the modem is not communicating with the network, the method then branches to step 412. At step 412, an attempt is made to upload an intelligent diagnostic agent via satellite link. In an alternative embodiment, the existing intelligent diagnostic agent may be sent a command to re-boot the MDD, to upgrade the operating system, or to perform remedial actions related to the communication link. In any event, an alternative diagnostic procedure is implemented, in response to a failure to communicate with the MDD over the preferred communication link.

The method proceeds from step 412 to decision block 414. At decision block 414, a determination is made as to whether the modem is communicating with the network, following the remedial actions taken in step 412. If the modem is communicating with the network, the method branches to step 404 and proceeds as described below. If the modem is not communicating with the network, the method branches to step 418 and a technician service call is arranged. The method proceeds from step 418 to step 428 and ends.

Returning now to decision block 406, if a determination is made that the intelligent diagnostic agent is not functional, the method branches to step 410. At step 410, an intelligent diagnostic agent is uploaded to the MDD via the modem communication link. The method proceeds to decision block 416. At decision block 416, a determination is made as to whether the intelligent diagnostic agent is functional, following the remedial action taken in step 410. If the intelligent diagnostic agent is not functional, the method branches to step 418 and a technician service call is arranged. If, on the other hand, a determination is made at decision block 416 that the intelligent diagnostic agent is functional, the method branches to step 408 and proceeds as described above.

Although the present invention has been described in connection with various exemplary embodiments, those of ordinary skill in the art will understand that many modifications can be made thereto within the scope of the claims that follow. Accordingly, it is not intended that the scope of the invention in any way be limited by the above description, but instead be determined entirely by reference to the claims that follow.

What is claimed is:

1. A method for analyzing the operation of a media delivery device, the method comprising the steps of:
determining whether a network connection is functional;
determining whether a first diagnostic agent is functional, in response to a determination that the network connection is functional;
causing the first diagnostic agent to collect diagnostic data associated with the media delivery device, in response to a determination that the first diagnostic agent is functional; and
analyzing the diagnostic data to determine an operational problem associated with the media delivery device.

2. The method of claim 1 further comprising the step of uploading the first diagnostic agent to the media delivery device over an alternative network connection, in response to a determination that the network connection is not functional.

3. The method of claim 1 further comprising the step of uploading a second diagnostic agent to the media delivery device, in response to a determination that the first diagnostic agent is not functional.

4. The method of claim 1 further comprising the step of remedying the operational problem.

5. The method of claim 4 further comprising the step of uploading a second diagnostic agent to the media delivery device, in response to a determination that the network connection is not functional.

6. A diagnostic tool for remotely analyzing and diagnosing the performance of a media distribution device, comprising:
a data adapter operative to maintain a communication link between the media distribution device and a media delivery service provider;
an intelligent diagnostic agent residing in the media distribution device and operative to collect diagnostic data associated with the media distribution device; and
a diagnostic service center operative to communicate with the intelligent diagnostic agent over the communication link to retrieve the diagnostic data and to determine an performance problem associated with the media delivery device.

7. The diagnostic tool of claim 6, wherein the performance problem is also associated with a second device functionally connected to the media distribution device.

8. The diagnostic tool of claim 6, wherein the media distribution device is a set-top box.

9. The diagnostic tool of claim 6, wherein the intelligent diagnostic agent is a program module residing in a system memory of the media distribution device.

10. The diagnostic tool of claim 9, wherein the intelligent diagnostic agent is executable in the system memory.

11. The diagnostic tool of claim 6, wherein the diagnostic service center can upload the diagnostic agent to the media distribution device.

12. The diagnostic tool of claim 11, wherein the diagnostic service center can determine whether the diagnostic agent is functional.

13. The diagnostic tool of claim 11, wherein the diagnostic service center can replace the diagnostic agent with a substitute diagnostic agent, in response to a determination that the diagnostic agent is not functional.

14. The diagnostic tool of claim 6, wherein the communication link is broadband connection,.

15. The diagnostic tool of claim 14, wherein the communication link is an asymmetric digital subscriber line.

16. The diagnostic tool of claim 6, wherein the communication link is a satellite connection.

17. The diagnostic tool of claim 6, wherein the diagnostic service center is further operative to remedy the performance problem.

18. The diagnostic tool of claim 17, wherein the diagnostic service center is further operative to remedy the performance problem by uploading a replacement program module to a system memory of the media distribution device.

19. The diagnostic tool of claim 17, wherein the diagnostic service center is further operative to remedy the performance problem by establishing a secondary communication link between the media distribution device and the media delivery service provider.

20. A self-diagnosing media distribution system, comprising:
a media delivery service provider operative to transmit a media content stream to a media distribution device;
a diagnostic service center for communicating with the media distribution device to retrieve diagnostic data from the media distribution device and to send remedial data to the media distribution device; and
an intelligent diagnostic agent residing in the media distribution device and operative to collect diagnostic data associated with the media distribution device and to transmit the diagnostic data to the diagnostic service center;
whereby a performance problem associated with the media delivery device can be remotely remedied.
